(19) United States
(12) Patent Application Publication
(10) Pub. No.: US 2018/0261723 A1
(43) Pub. Date: Sep. 13, 2018

(54) ULTRAVIOLET LIGHT EMITTING DEVICE AND METHOD FOR MANUFACTURING SAME

(71) Applicant: SEOUL VIOSYS CO., LTD., Ansan-si (KR)

(72) Inventors: Seong Kyu Jang, Ansan-si (KR); Kyu Ho Lee, Ansan-si (KR); Yeo Jin Yoon, Ansan-si (KR); Chi Hyun In, Ansan-si (KR); Jong Hyeon Chae, Ansan-si (KR); Hong Suk Cho, Ansan-si (KR)

(21) Appl. No.: 15/971,974

(22) Filed: May 4, 2018

Related U.S. Application Data
(63) Continuation of application No. PCT/KR2016/012460, filed on Nov. 1, 2016.

(30) Foreign Application Priority Data
Nov. 5, 2015 (KR) 10-2015-0154886
Dec. 17, 2015 (KR) 10-2015-0181169
Dec. 17, 2015 (KR) 10-2015-0181176

(51) Int. Cl. H01L 33/20; H01L 33/40; H01L 33/62; H01L 33/46; H01L 33/24; H01L 33/32; H01L 33/38; H01L 33/00

(52) U.S. Cl. CPC H01L 33/20; H01L 33/405; H01L 33/62; H01L 33/46; H01L 33/24; H01L 33/32; H01L 33/06; H01L 33/007; H01L 33/0095; H01L 2933/0016; H01L 2933/0025; H01L 2933/0066; H01L 33/38

(57) ABSTRACT

An ultraviolet light emitting device is disclosed. An ultraviolet light emitting device according to a first embodiment of the disclosed technology comprises: a substrate having a first surface and a second surface facing the first surface; and a light emitting diode comprising a first type semiconductor layer, an active layer which emits ultraviolet light, and a second type semiconductor layer, the light emitting diode being formed on the first surface of the substrate, wherein the surface area of the substrate divided by the light emitting area of the light emitting diode may be ≤6.5.

### CROSS-REFERENCE TO RELATED APPLICATION(S)

This patent document claims priority and benefits of International Application No. PCT/KR2016/012460 entitled “ULTRAVIOLET LIGHT EMITTING DEVICE AND METHOD FOR MANUFACTURING THE SAME” and filed on Nov. 1, 2016, which further claims to Korean Patent Application No. 10-2015-0154886 filed on Nov. 5, 2015 and Korean Patent Application Nos. 10-2015-0181169 and 10-2015-0181176 that were filed on Dec. 17, 2015. The entire contents of the aforementioned patent applications are incorporated herein by reference as part of this patent document.

### TECHNICAL FIELD

Embodiments of the disclosed technology relate to a UV (ultraviolet) light emitting device and, more particularly, to a UV light emitting device configured to improve light extraction efficiency and a method of manufacturing the same.

### BACKGROUND

UV light emitting devices have been widely used based on their various applicability to UV curing, sterilization, white light sources, medical equipment, equipment components, and so on. A deep UV light emitting device emits UV light having a shorter wavelength (light having a peak wavelength of about 340 nm or less, specifically in the range of about 200 nm to about 340 nm) than a near UV light emitting device (which emits light having a peak wavelength in the range of about 340 nm to about 400 nm) and exhibits strong luminous intensity with respect to light in the UVC range.

### SUMMARY

Embodiments of the disclosed technology provide a UV light emitting device having improved light extraction efficiency through increase or optimization of a surface area of a substrate with respect to the same luminous area.

Embodiments of the disclosed technology provide a UV light emitting device that can improve reliability while improving productivity upon separation of light emitting devices into individual chips, and a method of manufacturing the same.

Embodiments of the disclosed technology provide a UV light emitting device that can increase the intensity of light emitted from a side surface of a substrate thereof after separation of light emitting devices into individual chips, and a method of manufacturing the same.

Embodiments of the disclosed technology provide a UV light emitting device that includes a mesa having holes for improving luminous efficacy.

Embodiments of the disclosed technology provide a UV light emitting device that has improved luminous efficacy through improvement in reflection efficiency of a distributed Bragg reflector covering the holes of the mesa.

Other features and advantages of the disclosed technology will become apparent from the following detailed description.

In accordance with one aspect of the disclosed technology, a UV light emitting device includes: a substrate having a first surface and a second surface facing the first surface; and a light emitting diode formed on the first surface of the substrate and including a first type semiconductor layer, an active layer emitting UV light, and a second type semiconductor layer, wherein a ratio of surface area of the substrate to luminous area of the light emitting diode may be 6.5 or less (≤6.5).

In accordance with another aspect of the disclosed technology, a UV light emitting device includes: a substrate having a first surface and a second surface facing the first surface, the substrate being formed therein with at least one inner processing line; a light emitting diode formed on the first surface of the substrate and emitting UV light; and a scribing line formed on the first surface of the substrate and disposed between the light emitting diode and another light emitting diode adjacent to the light emitting diode.

In accordance with a further aspect of the disclosed technology, a method of manufacturing a light emitting device includes: preparing a substrate having a first surface and a second surface; forming a plurality of light emitting diodes on the first surface of the substrate; forming a scribing line on the first surface of the substrate to divide the plurality of light emitting diodes from each other; forming at least one inner processing line within the substrate; and separating the plurality of light emitting diodes into individual light emitting diodes along the scribing line.

In accordance with yet another aspect of the disclosed technology, a UV light emitting device includes: a first conductivity type semiconductor layer; a mesa including an active layer disposed on the first conductivity type semiconductor layer and emitting UV light and a second conductivity type semiconductor layer disposed on the active layer, the mesa having at least one hole formed through the active layer and the second conductivity type semiconductor layer to partially expose the first conductivity type semiconductor layer; a light reflective insulation layer at least partially covering a surface of the hole and including a distributed Bragg reflector; a first electrode electrically connected to the first conductivity type semiconductor layer; and a second electrode disposed on the mesa to cover the light reflective insulation layer and electrically connected to the second conductivity type semiconductor layer, wherein the mesa includes a first portion having a first width and a second portion having a second width smaller than the first width with reference to a plane of the mesa, and the second portion includes at least part of the hole.

In accordance with yet another aspect of the disclosed technology, a UV light emitting device includes: a first conductivity type semiconductor layer; a mesa including an active layer disposed on the first conductivity type semiconductor layer and emitting UV light and a second conductivity type semiconductor layer disposed on the active layer, the mesa having at least one hole formed through the active layer and the second conductivity type semiconductor layer to partially expose the first conductivity type semiconductor layer; a light reflective insulation layer at least partially covering a surface of the hole and including a distributed Bragg reflector; and a second electrode disposed on the mesa to cover the light reflective insulation layer and electrically connected to the second conductivity type semiconductor layer, wherein the mesa includes a first portion having a first width in a perpendicular direction with respect to a vector line x having an arbitrary direction with reference to a plane of the mesa; and a second portion having a second width in a perpendicular direction with respect to the vector line x, the first width being greater than the second width, the second portion includes at least a portion of the hole, and the portion of the hole included the second portion has an elongated shape extending in a direction of the vector line x.

According to embodiments, a surface area of a substrate of a light emitting device is increased to increase an area of a side surface of the substrate, through which light is extracted, without increasing the thickness of the substrate, thereby improving light extraction efficiency of the light emitting device.

According to embodiments, a plurality of inner processing lines is formed within the substrate through a rear surface of the substrate so as not to damage a chip while forming a V-shaped scribing line on the surface of the substrate, whereby a process of separating light emitting devices into individual chips can be stably performed, thereby improving yield and reliability.

According to embodiments, after the process of separating light emitting devices into individual chips, a plurality of modified regions is formed on the side surface of the substrate by the inner processing lines formed within the substrate such that a critical angle on the side surface of the light emitting device corresponding to a light exit surface is changed, thereby improving light extraction efficiency.

According to embodiments, the UV light emitting device includes a light reflective insulation layer, which covers a hole formed to at least partially penetrate the mesa, thereby improving luminous efficacy. In particular, the UV light emitting device can reduce the ratio of light absorbed by the second conductivity type semiconductor layer through the hole and the light reflective insulation layer. Furthermore, the hole is included into a second portion of the mesa, which has a relatively narrow width, and has an elongated shape extending with respect to the second portion, thereby further improving luminous efficacy.

It should be understood that the disclosed technology is not limited to the aforementioned effects and include all advantageous effects deducible from the detailed description of the disclosed technology or the appended claims.

### BRIEF DESCRIPTION OF THE DRAWINGS

FIG. 1 is a plan view of a light emitting device according to embodiments of the disclosed technology.

FIG. 2 is a cross-sectional view of the light emitting device taken along line A-A′ of FIG. 1.

FIG. 3 is a side sectional view of a light emitting device according to a first embodiment of the disclosed technology mounted on a submount.

FIG. 4 is a cross-sectional view of a modification of the light emitting device according to a first embodiment of the disclosed technology.

FIG. 5 is a graph depicting the relationship between luminous power Po and surface area of a substrate of the light emitting device according to a first embodiment.

FIG. 6A to FIG. 6D are photographs depicting an upper surface and a cross-section of the light emitting device according to a first embodiment.

FIG. 7 is a cross-sectional view of a light emitting device according to a second embodiment of the disclosed technology, taken along line A-A′ of FIG. 1.

FIG. 8 to FIG. 10 are cross-sectional views depicting a method of manufacturing the light emitting device according to a second embodiment of the disclosed technology.

FIG. 11A and FIG. 11B are photographs depicting an upper surface and a cross-section of the light emitting device according to a second embodiment, in which a plurality of inner processing lines is formed.

FIG. 12A and FIG. 12B are photographs depicting an upper surface and a cross-section of the light emitting device according to a second embodiment, in which a plurality of inner processing lines and a V-shaped groove are formed.

FIG. 13 is a graph depicting the relationship between luminous power Po and the number of inner processing lines in the light emitting device according to a second embodiment of the disclosed technology.

FIG. 14A to FIG. 14C are schematic plan views of a light emitting device according to a third embodiment of the disclosed technology.

FIG. 15 and FIG. 16 are cross-sectional views taken along lines A-A′ and B-B′ of FIG. 14A.

FIG. 17 is a plan view illustrating a mesa and a hole of the light emitting device according to a third embodiment of the disclosed technology.

FIG. 18 is a plan view of a modification of the light emitting device according to a third embodiment of the disclosed technology.

FIG. 19 is a graph depicting reflectivity of a light reflective insulation layer of the UV light emitting device according to a third embodiment of the disclosed technology.

FIG. 20 is a perspective view of a light emitting device package using a light emitting device according to embodiments of the disclosed technology.

### DETAILED DESCRIPTION

Hereinafter, embodiments of the disclosed technology will be described in detail with reference to the accompanying drawings. The following embodiments are provided by way of example so as to facilitate understanding of various implementations to those skilled in the art to which the disclosed technology pertains. Accordingly, the disclosed technology is not limited to the embodiments disclosed herein and can also be implemented in different forms. In the drawings, widths, lengths, thicknesses, and the like of elements can be exaggerated for clarity and descriptive purposes. When an element is referred to as being “disposed above” or “disposed on” another element, it can be directly “disposed above” or “disposed on” the other element, or intervening elements can be present. Throughout the specification, like reference numerals denote like elements having the same or similar functions.

The UV light emitting device has a problem of low light extraction efficiency due to absorption or extinction of UV light therein instead of emitting large amounts of UV light. In order to solve this problem, a technique of forming a substrate to a thickness of greater than 120 μm for the purpose of improving extraction efficiency of light extracted to the outside of the substrate has been investigated. However, an excessive increase in thickness of the substrate causes difficulty in separation of a wafer into individual chips and in attachment of a lens for formation of a package.

In addition, each of light emitting diode chips constituting a light emitting device is generally fabricated by growing semiconductor layers on a single wafer, followed by separating the wafer into individual chips. Here, the process of separating the wafer into individual chips may be performed by scribing or breaking using a tip, a blade, or a laser beam. Although laser scribing can improve productivity through increase in work speed, chips (electrode or active layer) can be damaged by laser beams, thereby causing property degradation of a semiconductor light emitting device.

Further, light emitted from a UV light emitting device has a shorter wavelength than light emitted from a visible light emitting device, and nitride semiconductors for UV light emitting devices have a higher Al content than nitride semiconductors for visible light emitting devices. Due to such reasons, the UV light emitting device has very different electrical and optical characteristics than the visible light emitting device. Accordingly, if the structure of the visible light emitting device is applied to the UV light emitting device, there can be a significant deterioration in electrical and optical characteristics.

In recognition of the problems above, the disclosed technology provides various implementations of a light emitting device with an improved light extraction efficiency. In accordance with one embodiment of the disclosed technology, a UV light emitting device includes: a substrate having a first surface and a second surface facing the first surface; and a light emitting diode formed on the first surface of the substrate and including a first type semiconductor layer, an active layer emitting UV light, and a second type semiconductor layer, wherein a ratio of surface area of the substrate to luminous area of the light emitting diode may be equal to or less than 6.5 (≤6.5).

In one embodiment, the substrate may have a thickness of 200 μm to 400 μm.

In one embodiment, the substrate may have a surface area of 350 μm×410 μm to 550 μm×550 μm.

In one embodiment, the substrate may include at least one selected from the group consisting of sapphire (Al₂O₃), SiC, Si, GaAs, GaN, ZnO, Si, GaP, InP, Ge, and AlN substrates.

In one embodiment, the substrate may include a plurality of modified regions formed on the second surface or a side surface thereof.

In one embodiment, the light emitting structure may have a luminous area of 35,000 μm² to 40,000 μm².

In one embodiment, the luminous area of the light emitting diode may be a surface area of the active layer.

In one embodiment, the light emitting device may further include a first contact electrode formed on the first type semiconductor layer and including a reflective material.

In one embodiment, the light emitting device may further include a submount to which the light emitting device is flip-chip bonded.

In accordance with another embodiment of the disclosed technology, a UV light emitting device includes: a substrate having a first surface and a second surface facing the first surface, the substrate being formed therein with at least one inner processing line; light emitting diodes formed on the first surface of the substrate and emitting UV light; and a scribing line formed on the first surface of the substrate and disposed between adjacent two light emitting diodes.

In one embodiment, the number of inner processing lines formed in the substrate may be three or more.

In one embodiment, the inner processing lines may be separated parallel to each other.

In one embodiment, the inner processing line may be formed by irradiation with pulsed laser beams.

In one embodiment, the scribing line may include a V-shaped groove.

In one embodiment, the scribing line may be formed by laser irradiation.

In one embodiment, the substrate may have a thickness of 200 μm to 300 μm.

In one embodiment, the light emitting diode may include a first type semiconductor layer, an active layer, and a second type semiconductor layer, and a first contact electrode including a reflective material may be formed on the first type semiconductor layer.

In accordance with a further embodiment of the disclosed technology, a method of manufacturing a light emitting device includes: preparing a substrate having a first surface and a second surface; forming a plurality of light emitting diodes on the first surface of the substrate; forming a scribing line on the first surface of the substrate to divide the plurality of light emitting diodes from each other; forming at least one inner processing line within the substrate; and separating the plurality of light emitting diodes into individual light emitting diodes along the scribing line.

In one embodiment, in preparation of the substrate, the substrate may have a thickness of 200 μm to 300 μm.

In one embodiment, the inner processing line may be formed by irradiation with pulsed laser beams through the second surface of substrate.

In one embodiment, in formation of the scribing line, the scribing line may be formed in the form of a V-shaped groove through irradiation with laser beams.

In one embodiment, forming the inner processing line may include moving or rotating a laser system with respect to at least one of an X-axis, a Y-axis, and a Z-axis.

In one embodiment, forming the inner processing line may include moving or rotating the substrate placed on a processing plane of the laser system with respect to at least one of the X-axis, the Y-axis, and the Z-axis.

In accordance with yet another embodiment of the disclosed technology, a UV light emitting device includes: a first conductivity type semiconductor layer; a mesa including an active layer disposed on the first conductivity type semiconductor layer and emitting UV light and a second conductivity type semiconductor layer disposed on the active layer, the mesa having at least one hole formed through the active layer and the second conductivity type semiconductor layer to partially expose the first conductivity type semiconductor layer; a light reflective insulation layer at least partially covering a surface of the hole and including a distributed Bragg reflector; a first electrode electrically connected to the first conductivity type semiconductor layer; and a second electrode disposed on the mesa to cover the light reflective insulation layer and electrically connected to the second conductivity type semiconductor layer, wherein the mesa includes a first portion having a first width and a second portion having a second width smaller than the first width on an upper surface of the mesa, and the second portion includes at least part of the hole.

The portion of the hole included in the second portion may have an elongated shape extending in a perpendicular direction with respect to the second width.

The mesa may include at least two first portions and the second portion may be disposed between the two first portions.

The mesa may have an H shape in plan view.

The hole may have an H shape in plan view.

The mesa may include a plurality of holes, at least one of the plurality of holes may be included in the second portion, and the at least one hole included in the second portion may have an elongated shape extending in a perpendicular direction with respect to the second width.

The light reflective insulation layer may cover an upper surface of the mesa around the hole.

A surface of the first conductivity type semiconductor layer exposed through the hole may be separated from the second electrode by the light reflective insulation layer to be electrically insulated therefrom.

The distributed Bragg reflector of the light reflective insulation layer may include a stacked structure in which ZrO₂ layers and SiO₂ layers are repeatedly stacked one above another.

The light reflective insulation layer may further include an interfacial layer disposed under the distributed Bragg reflector, formed of SiO₂ and having a greater thickness than the ZrO₂ layer and the SiO₂ layer of the distributed Bragg reflector.

The light reflective insulation layer may include a first distributed Bragg reflector reflecting light having a relatively long wavelength; and a second distributed Bragg reflector disposed on the first distributed Bragg reflector and reflecting light having a relatively short wavelength.

The second conductivity type semiconductor layer may include a nitride semiconductor having an energy bandgap of 3.0 eV to 4.0 eV.

The second conductivity type semiconductor layer may include P-GaN.

The active layer may emit light having a peak wavelength of 300 nm or less.

The first electrode may cover 50% or more of an upper surface of the first conductivity type semiconductor layer.

The UV light emitting device may further include an insulation layer covering the first electrode and the second electrode and including a first opening and a second opening partially exposing the first electrode and the second electrode, respectively.

The UV light emitting device may further include a first pad electrode disposed on the insulation layer and electrically connected to the first electrode through the first opening; and a second pad electrode disposed on the insulation layer and electrically connected to the second electrode through the second opening.

In accordance with yet another embodiment of the disclosed technology, a UV light emitting device includes: a first conductivity type semiconductor layer; a mesa including an active layer disposed on the first conductivity type semiconductor layer and emitting UV light and a second conductivity type semiconductor layer disposed on the active layer, the mesa having at least one hole formed through the active layer and the second conductivity type semiconductor layer to partially expose the first conductivity type semiconductor layer; a light reflective insulation layer at least partially covering a surface of the hole and including a distributed Bragg reflector; and a second electrode disposed on the mesa to cover the light reflective insulation layer and electrically connected to the second conductivity type semiconductor layer, wherein the mesa includes a first portion having a first width in a perpendicular direction with respect to a vector line x having an arbitrary direction on an upper surface of the mesa; and a second portion having a second width in the perpendicular direction with respect to the vector line x, the first width being greater than the second width, the second portion includes at least a portion of the hole, and the portion of the hole included the second portion has an elongated shape extending in a direction of the vector line x.

The second electrode may include a reflective layer and a cover layer covering the reflective layer.

The distributed Bragg reflector may include a stacked structure in which ZrO₂ layers and SiO₂ layers are repeatedly stacked one above another.

Embodiments of the disclosed technology will now be described in more detail with reference to the accompanying drawings.

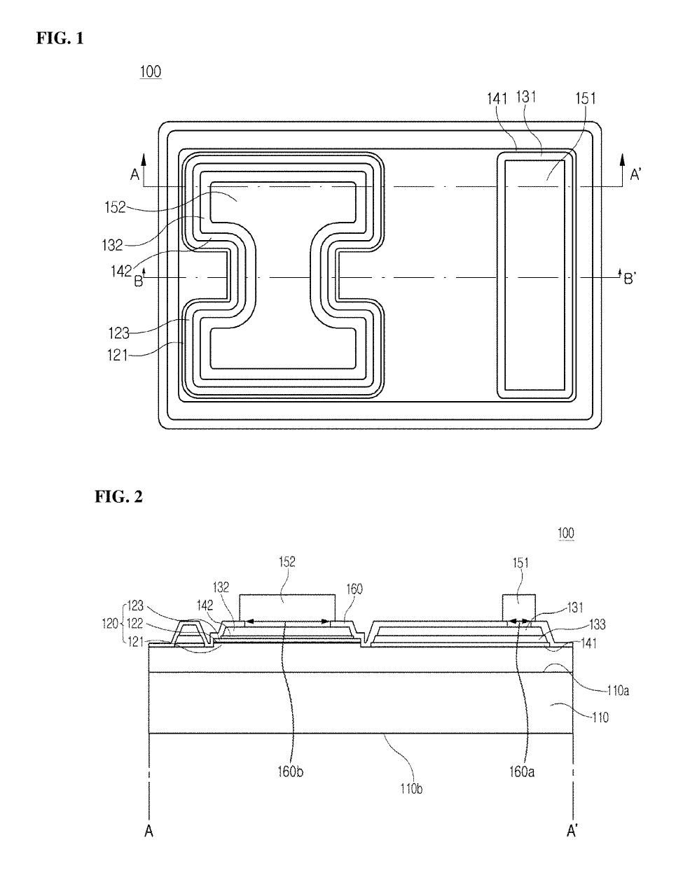

FIG. 1 is a plan view of a light emitting device according to embodiments of the disclosed technology. The disclosed technology may be realized by various embodiments including first to third embodiments. Here, the plan view of FIG. 1 can be commonly applied to the first and second embodiments. Specifically, FIG. 1 is a plan view illustrating an upper surface of the light emitting device according to the embodiments of the disclosed technology.

Referring to FIG. 1, the light emitting device 100 according to the embodiments may include a first bump electrode 151 and a second bump electrode 152 disposed on one surface of a substrate and separated from each other.

The first bump electrode 151 may be formed on a first pad electrode 131, which may be formed on a first contact electrode 141. The first contact electrode 141 forms ohmic contact with a first type semiconductor layer and is disposed in an exposed region of the first type semiconductor layer excluding a mesa in order to improve current spreading of the UV light emitting device. The first contact electrode 141 may include a reflective material.

The reflective material serves to reflect UV light, which has been reflected by the substrate 110 toward the first contact electrode 141, to the substrate 110, thereby improving light extraction efficiency.

The reflective material may include a highly conductive metallic material. For example, the reflective material may include at least one of Ag, Ni, Al, Rh, Pd, Ir, Ru, Mg, Zn, Pt, Au, or Hf. In one embodiment, the reflective material may include Al having high reflectance in the UV wavelength band and may be formed in a matrix of islands, a plurality of lines, or a mesh structure.

The second bump electrode 152 may be formed on a second pad electrode 132, which may be formed on a second contact electrode 142. The second contact electrode 142 may be formed on a second type semiconductor layer.

Indentations are formed at both sides of the second bump electrode 152, the second pad electrode 132 and the second contact electrode 142. The indentations are symmetrically formed at one side adjacent to the first bump electrode 151, the first pad electrode 131 and the first contact electrode 141 and at the other side opposite the one side.

### First Embodiment

FIG. 2 is a cross-sectional view of the light emitting device according to the first embodiment taken along line A-A′ of FIG. 1.

Referring to FIG. 2, the light emitting device 100 according to this embodiment may be a UV light emitting device that can emit light in the UV wavelength band. For example, the UV light emitting may emit deep UV light having a wavelength of 360 nm or less.

The UV light emitting device according to this embodiment may include a substrate 110 and a light emitting structure 120.

The substrate 110 serves to grow a monocrystalline semiconductor thereon and may include a first surface 110a and a second surface 110b facing the first surface 110a.

Although the substrate 110 can be formed of or include zinc oxide (ZnO), gallium nitride (GaN), silicon carbide (SiC), aluminum nitride (AlN), or others, the substrate 110 may be generally formed of a transparent material including sapphire, which has high orientation and is free from cracks or scratches through precise polishing.

The light emitting device 100 may further include a buffer layer (not shown) formed on the first surface 110a of the substrate 110 to relieve lattice mismatch between the substrate 110 and a first type semiconductor layer 121. The buffer layer may be composed of a single layer or multiple layers. The buffer layer composed of multiple layers may include a low temperature buffer layer and a high temperature buffer layer.

The light emitting structure 120 is a structure that converts energy produced by recombination of electrons and holes into light, and may be formed on the substrate 110 using an apparatus for growth of a semiconductor layer, after surface treatment of the substrate 110 through a wet or dry process.

The light emitting structure 120 may include the first type semiconductor layer 121, an active layer 122, and a second type semiconductor layer 123, which are sequentially stacked on the first surface 110a of the substrate 110.

The first type semiconductor layer 121 may be formed on the first surface 110a of the substrate 110 to be partially exposed, as shown in FIG. 2. The exposed region of the first type semiconductor layer 121 may be formed by partially removing the active layer 122 and the second type semiconductor layer 123 through mesa etching. Upon mesa etching, the first type semiconductor layer 121 may also be partially removed.

The first type semiconductor layer 121 may be formed of or include a III-V based compound semiconductor represented by InₓAl_{y}Ga_{1-x-y}N (0≤x≤1, 0≤y≤1, 0≤x+y≤1) and may be doped with first type dopants, for example, n-type dopants. The first type semiconductor layer 121 may be composed of a single layer or multiple layers. The n-type dopants may include at least one of Si, Ge, Sn, or others.

The active layer 122 may be disposed on the first type semiconductor layer 121 and generates light through recombination of electrons and holes injected from the first type semiconductor layer 121 and the second type semiconductor layer 123. In one embodiment, the active layer 122 may have a multi-quantum well structure in order to improve electron-hole recombination efficiency. The composition elements and ratio of the active layer 122 may be determined to emit UV light having a desired peak wavelength of, for example, 200 nm to 360 nm.

UV light generated from the active layer 122 is composed of or includes TE polarized light and TM polarized light. The TE polarized light travels in the perpendicular direction with respect to a surface of the active layer 122, whereas the TM polarized light travels in the horizontal direction with respect to the surface of the active layer 122.

Most UV light is TM polarized light. In the light emitting structure 120, however, since a side surface of the active layer 122 has a much smaller area than an upper or lower surface of the active layer 122, a very small amount of UV light is extracted through the side surface of the active layer 122. Accordingly, the amount of UV light emitted through the substrate 110 is much smaller than the amount of visible light emitted therethrough.

According to this embodiment, the surface area of the substrate 110 is maximized in an allowable range, thereby maximizing the side volume of the substrate 110 through which light is extracted. The allowable range will be described in detail below.

The second type semiconductor layer 123 may be formed on the active layer 122. The second type semiconductor layer 123 may be formed of a III-V based compound semiconductor represented by InₓAl_{y}Ga_{1-x-y}N (0≤x≤1, 0≤y≤1, 0≤x+y≤1) and may be doped with second type dopants, for example, p-type dopants. The second type semiconductor layer 123 may be composed of a single layer or multiple layers. The p-type dopants may include Mg, Zn, Be, or others.

The first pad electrode 131 and the second pad electrode 132 may be disposed on upper surfaces of the first type semiconductor layer 121 and the second type semiconductor layer 123, respectively. The first pad electrode 131 and the second pad electrode 132 may include at least one of Ni, Cr, Ti, Al, Ag, or Au. The first pad electrode 131 may be electrically connected to the exposed portion of the first type semiconductor layer 121 and the second pad electrode 132 may be electrically connected to the exposed portion of the second type semiconductor layer 123.

The light emitting device may further include a pad layer 133 interposed between the first type semiconductor layer 121 and the first pad electrode 131. The pad layer 133 compensates for a height difference between the first pad electrode 131 and the second pad electrode 132 such that an upper surface of the first pad electrode 131 is flush with an upper surface of the second pad electrode 132. That is, although the first pad electrode 131 can be formed at a lower position than the second pad electrode 132 due to mesa etching of the first type semiconductor layer 121, the pad layer 133 formed under the first pad electrode 131 makes the first pad electrode 131 flush with the second pad electrode 132. The pad layer 133 may include, for example, Ti or Au.

In addition, the light emitting device may further include a first contact electrode 141 and a second contact electrode 142 between the first type semiconductor layer 121 and the pad layer 133 and between the second type semiconductor layer 123 and the second pad electrode 132 to form ohmic contact therebetween, respectively. The first contact electrode 141 may include, for example, at least one of Cr, Ti, Al, or Au, and the second contact electrode 142 may include, for example, at least one of Ni or Au.

In this embodiment, the light emitting device 100 may further include a passivation layer 160 to protect the light emitting structure 120 from external environments.

The passivation layer 160 may be formed of or include an insulation layer including a silicon oxide layer or a silicon nitride layer. The passivation layer 160 may include openings 160a, 160b, which partially expose the surfaces of the first pad electrode 131 and the second pad electrode 132.

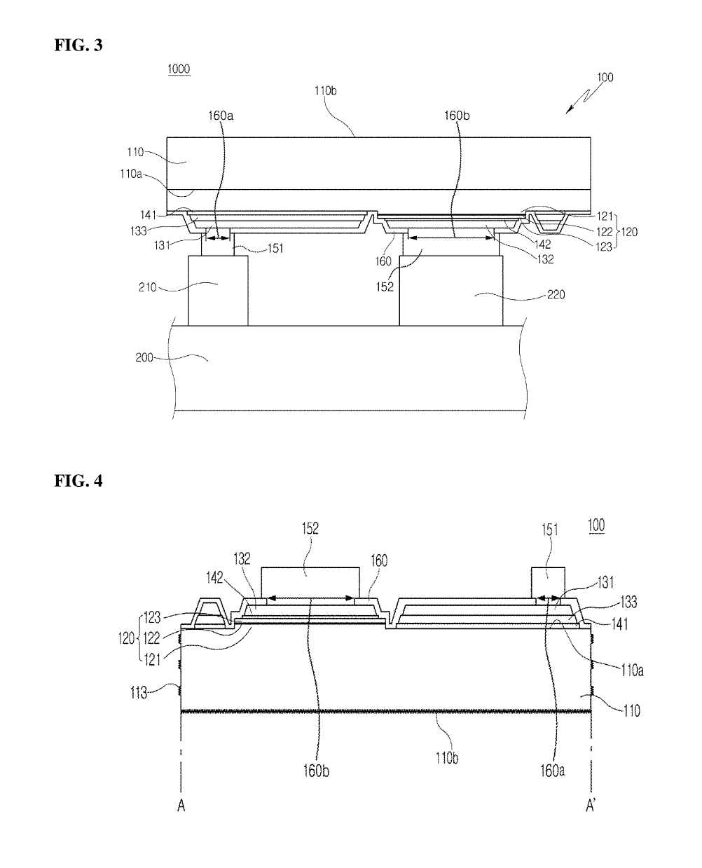

Referring to FIG. 3, the light emitting device 100 may be mounted in the form of a flip-chip on a submount 200. In this structure, the light emitting device 100 may further include a first bump electrode 151 and a second bump electrode 152 to be electrically connected to the submount 200.

The first bump electrode 151 may be disposed on the first pad electrode 131 and the second bump electrode 152 may be disposed on the second pad electrode 132. The first bump electrode 151 and the second bump electrode 152 may include, for example, Ti, Au or Cr.

The submount 200 includes a first electrode layer 210 and a second electrode layer 220 on one surface thereof, and the first bump electrode 151 and the second bump electrode 152 of the light emitting device 100 may be electrically connected to the first electrode layer 210 and the second electrode layer 220, respectively.

Here, the bump electrodes 151, 152 may be formed to cover the surfaces of the pad electrodes 131, 132 and a portion of the surface of the passivation layer 160. Thus, for bonding reliability, a portion of the passivation layer 160 is interposed between the pad electrodes 131, 132 and the bump electrodes 151, 152, which are formed to cover the exposed portions of the pad electrodes 131, 132 and the portion of the surface of the passivation layer 160.

The substrate 110 may be formed in a hexahedral shape having a predetermined length, width and thickness. For example, the substrate 110 may have a thickness of 200 μm to 400 μm.

When one surface of the substrate 110 has an increased surface area, the side surface of the substrate through which light is extracted has an increased surface area, whereby the quantity of light can be increased without increasing the thickness of the substrate, thereby minimizing limitations due to the thickness of the substrate upon packaging of the light emitting device. Thus, it is desirable that the substrate be formed to have as large an area within the allowable range as possible.

Here, even when the overall surface area of the substrate 110 increases, there can be a problem of light loss if the area of the side surface of the substrate through which light is extracted increases over a critical value. Thus, in order to optimize light extraction efficiency, the surface area of the substrate may be increased such that the ratio of the surface area of the substrate area to a luminous area of the light emitting diode is equal to or less than 6.5 (≤6.5).

Here, the surface area of the substrate may be a surface area of the first surface 110a of the substrate 110 and the luminous area of the light emitting structure 120 may be a surface area of the active layer 122. For example, the substrate 110 may have a surface area of 350 μm×410 μm to 650 μm×650 μm and the light emitting structure 120 may have a luminous area of 35,000 μm² to 40,000 μm².

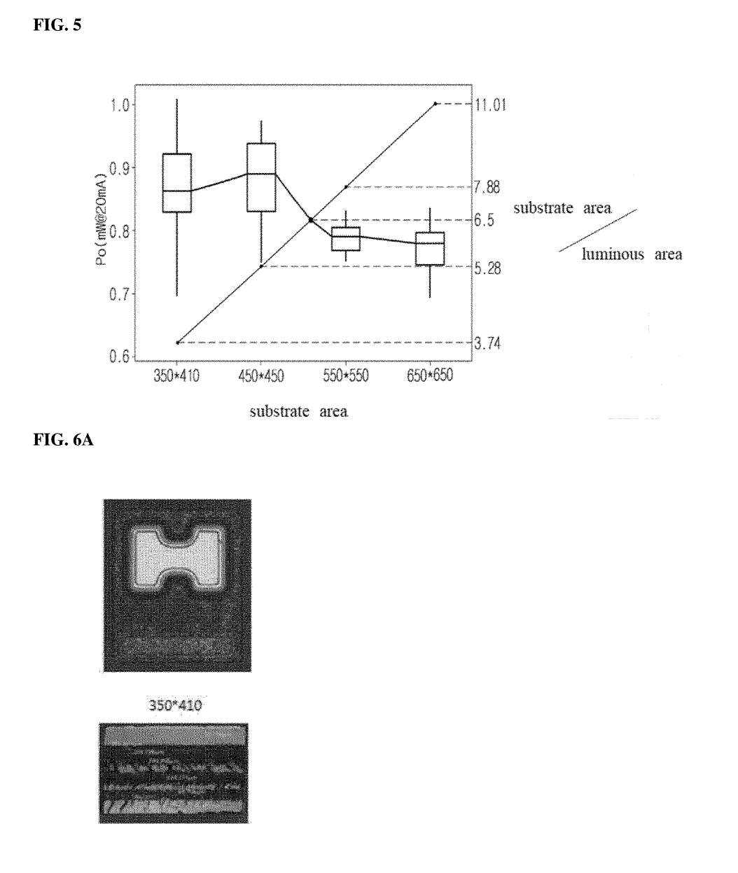

According to this embodiment, when the surface area of the substrate is increased such that the ratio of the surface area of the substrate area to the luminous area of the light emitting diode is equal to or less than 6.5 (≤6.5) under conditions that the substrate 110 has a thickness of 200 μm to 400 μm and the light emitting structure 120 has a fixed luminous area, the light emitting device can have higher luminous efficacy than typical light emitting devices. This will be described again below with reference to FIG. 5.

If the surface area of the substrate is increased, a separation distance between the first bump electrode (or first pad electrode) and the second bump electrode (or second pad electrode) formed on the first surface 110a of the substrate 110 and a separation distance between each of the bump electrodes and a periphery of the substrate can be increased, thereby causing uneven current spreading on the overall surface of the substrate due to current crowding between the bump electrodes. Therefore, it is desirable that the distance between the bump electrodes be kept constant.

In addition, according to this embodiment, the first contact electrode 141 may include a reflective material. The reflective material serves to reflect light, which has been reflected from the substrate 110 to the first contact electrode 141, toward the substrate 110, thereby improving light extraction efficiency.

The reflective material may be formed of a highly conductive metallic material. For example, the reflective material may include at least one of Ag, Ni, Al, Rh, Pd, Ir, Ru, Mg, Zn, Pt, Au, or Hf. In one embodiment, the reflective material may include Al having high reflectance in the UV wavelength band and may be formed in a matrix of islands, a plurality of lines, or a mesh structure.

Referring to FIG. 2 and FIG. 3, a method of manufacturing the light emitting device according to the first embodiment will be described.

First, a substrate 110 is prepared and semiconductor layers including a first type semiconductor layer 121, an active layer 122 and a second type semiconductor layer 123 are sequentially formed on one surface of the substrate 110. The substrate 110 may be a sapphire substrate having a thickness of 200 μm to 400 μm. The substrate 110 may have a pattern formed thereon through a mask such that light emitting devices can be realized on one wafer to have various sizes, for example, 350 μm×410 μm, 450 μm×450 μm, 550 μm×550 μm, 650 μm×650 μm, and others.

The semiconductor layers, such as the first type semiconductor layer 121, the active layer 122 and the second type semiconductor layer 123, may be formed by a typical method of forming semiconductor layers, for example, MOCVD, e-beam evaporation, epitaxial growth, or others.

Then, the first type semiconductor layer 121, the active layer 122 and the second type semiconductor layer 123 are subjected to etching and separation to form a plurality of light emitting structures 120.

The plurality of light emitting structures 120 each including the first type semiconductor layer 121, the active layer 122 and the second type semiconductor layer 123 is formed by mesa etching so as to partially expose the first type semiconductor layer 121.

Thereafter, a first pad electrode 131 and a second pad electrode 132 may be formed on the first type semiconductor layer 121 and the second type semiconductor layer 123, respectively.

Alternatively, a first contact electrode 141 and a second contact electrode 142 may be formed to contact the semiconductor layers 121, 123 through openings, followed by forming the first pad electrode 131 and the second pad electrode 132 on the first contact electrode 141 and the second contact electrode 142, respectively.

Next, a passivation layer 160 is formed on the entire surface of the substrate 110 to protect the first type semiconductor layer 121, the second type semiconductor layer 123, the first pad electrode 131 and the second pad electrode 132 of the light emitting structures 120. The passivation layer 160 may be formed with openings which partially expose the first pad electrode 131 and the second pad electrodes 132.

Then, a first bump electrode 151 and a second bump electrode 152 are formed on the first pad electrode 131 and the second pad electrode 132, respectively, to form the plurality of light emitting structures 120 separated from each other on one surface of the substrate 110, followed by dividing the substrate 110 so as to separate the light emitting structures 120 into individual light emitting structures, thereby providing the light emitting devices 100 as shown in FIG. 2.

Further, a submount 200 including a first electrode layer 210 and a second electrode layer 220 that are formed on one surface thereof is prepared separately from the process of manufacturing the light emitting devices 100 through division of the substrate 110.

Thereafter, the light emitting device 100 is aligned with the submount 200 such that the first bump electrode 151 and the second bump electrode 152 of the light emitting device 100 correspond to the first electrode layer 210 and the second electrode layer 220 of the submount 200, respectively, followed by flip bonding the electrode layers 210, 220 to the bump electrodes 151, 152, thereby forming a light emitting device assembly as shown in FIG. 3. Here, flip bonding may be performed by a thermal-ultrasonic method or a thermal compression method.

FIG. 4 is a cross-sectional view of a modification of the light emitting device according to the first embodiment of the disclosed technology.

Referring to FIG. 4, the light emitting device 100 according to this embodiment may include a plurality of modified regions 113 on the side surface and the second surface 110b of the substrate 110 in order to increase the overall surface area of the substrate 110.

Specifically, the light emitting device 100 according to this embodiment include the modified regions 113, such as protrusions, on the side surface and the second surface 110b of the substrate 110 to improve light extraction efficiency with respect to light traveling to the side surface of the substrate 110, thereby improving luminous efficacy.

The modified regions 113 may be previously formed on the side surface and the second surface 110b of the substrate 110 or may be formed thereon by blasting or laser beams during or after the process of dividing the substrate 110.

The modified regions 113 may have a height of 100 nm to 1 μm. The modified regions 113 may be arranged at regular or irregular intervals on the side surface and the second surface 110b of the substrate 110. The modified regions 113 may be formed in the same shapes or various shapes and may have the same size of different sizes.

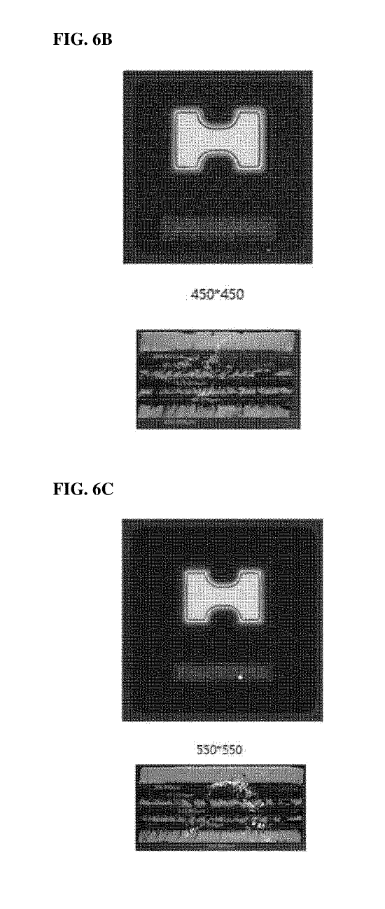

FIG. 5 is a graph depicting the relationship between the luminous power Po and the surface area of the substrate of the light emitting device according to the first embodiment, and FIG. 6A to FIG. 6D are photographs each including two portions depicting an upper surface and a cross-section of the light emitting device according to the first embodiment.

Referring to FIG. 5 and FIG. 6A to FIG. 6D, after preparation of the light emitting device according to this embodiment, the luminous power Po of the light emitting device was measured upon application of an electric current of 20 mA to the light emitting device. In addition, after manufacture of a light emitting device package 1000, the luminous power was measured under the same conditions.

Here, the substrate in each of the light emitting device and the light emitting device package has a thickness of 250 μm, and the measurement results are shown in Table 1.

TABLE 1

| | | | | |
|---|---|---|---|---|
| Substrate area | 350 μm × | 450 μm × | 550 μm × | 650 μm × |
| | 410 μm | 450 μm | 550 μm | 650 μm |
| | 143,500 μm² | 202,520 μm² | 302,500 μm² | 422,500 μm² |
| Luminous area | 38,380 μm² | 38,380 μm² | 38,380 μm² | 38,380 μm² |
| Substrate | 3.74 | 5.28 | 7.88 | 11.01 |
| are/Luminous | | | | |
| area | | | | |

Upon application of an electric current of 20 mA to the light emitting device package 1000, the light emitting device package 1000 had a luminous power of 0.857 mW when the substrate 110 had a surface area of 350 μm×410 μm as shown in FIG. 6A, a luminous power of 0.880 mW when the substrate 110 had a surface area of 450 μm×450 μm as shown in FIG. 6B, a luminous power of 0.789 mW when the substrate 110 had a surface area of 550 μm×550 μm as shown in FIG. 6C, and a luminous power of 0.769 mW when the substrate 110 had a surface area of 650 μm×650 μm as shown in FIG. 6D. This result shows that the luminous power decreases when the surface area of the substrate is in the range of 450 μm×450 μm to 550 μm×550 μm. Here, it is assumed that the luminous area of the light emitting diode is kept constant, that is, 38,380 μm².

This result shows that an excessive increase in the surface area of the substrate can cause decrease in the quantity of light extracted through the side surface of the substrate.

Here, an intersection point between a gradient indicating the ratio of the surface area of the substrate to the luminous area of the light emitting diode and the luminous power is 6.5. Thus, it can be seen that the luminous power of each of the light emitting device according to this embodiment and the light emitting device package including the same increases with increasing surface area of the substrate under the condition that the ratio of the surface area of the substrate to the luminous area of the light emitting diode is 6.5 or less. Thus, a light emitting device package fabricated using a light emitting device to which the substrate satisfying the above conditions is applied can have further improved light extraction efficiency.

Here, although this experiment was performed using the light emitting device packages fabricated using the light emitting devices including the substrates having a surface area in the range of 350 μm×410 μm to 650 μm×650 μm, it should be understood that this experiment was provided by way of example and a substrate having a surface area of less than 350 μm×410 μm may also be applied to the light emitting device according to this embodiment. That is, according to this embodiment, it does not mean that a minimum ratio of the surface area of the substrate to the luminous area of the light emitting diode is 3.74.

### Second Embodiment

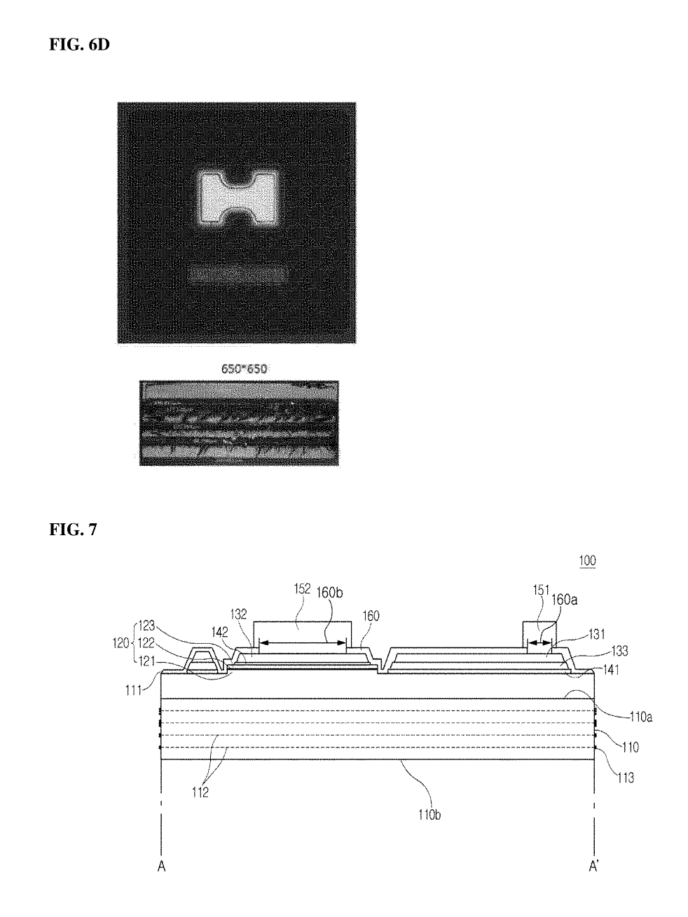

FIG. 7 is a cross-sectional view of a light emitting device according to a second embodiment of the disclosed technology, taken along line A-A′ of FIG. 1. Referring to FIG. 7, the light emitting device according to this embodiment is substantially similar to the light emitting device shown in FIG. 2 except for the shape of the substrate 110. Thus, the following description will focus on different features of the light emitting device according to this embodiment and description of the same components will be omitted.

Referring to FIG. 7, the substrate 110 may be formed in a hexahedral shape having a predetermined length, width and thickness and a scribing line 111 may be formed on the first surface 110a of the substrate 110 in order to facilitate separation of light emitting devices into individual chips.

Further, the substrate 110 may have one or more inner processing lines 112 formed therein and separated from each other. In consideration of packaging of the light emitting device, the substrate 110 may have a thickness of 200 μm to 300 μm in order to improve utilization in a limited space, without being limited thereto.

Here, since increase in the surface area of the side surface of the substrate 110 can cause increase in the quantity of light emitted therethrough, it is desirable that the surface area of the side surface of the substrate be increased as large as possible within the allowable range without increasing the thickness of the substrate.

Accordingly, the inner processing lines 112 may be formed at regular intervals within the substrate 110 by irradiation with laser beams, and a plurality of modified regions 113 may be evenly or unevenly formed on the side surface of the substrate in the process of separating light emitting devices into individual chips due to deformation of the substrate upon formation of the inner processing lines 112. With the modified regions 113, the side surface of the substrate 110 has an increased surface area without change in thickness of the substrate 110.

The modified regions 113 may have a height of 100 nm to 1 μm. The modified regions 113 may be arranged at regular or irregular intervals on the other surface or the side surface of the substrate 110, may be formed in the same shape or various shapes, and may have the same size or different sizes.

Thus, with the structure wherein the surface area of the side surface of the substrate 110 is increased under the condition that the substrate 110 has a thickness of 200 μm to 400 μm, the light emitting device can have improved luminous efficacy. This will be described below with reference to FIG. 10.

Although not shown in the drawings, a plurality of modified regions may be formed on the second surface 110b of the substrate 110 in order to increase the overall surface area of the substrate while increasing the light scattering ratio between the substrate and the light emitting diode, thereby improving external light extraction efficiency.

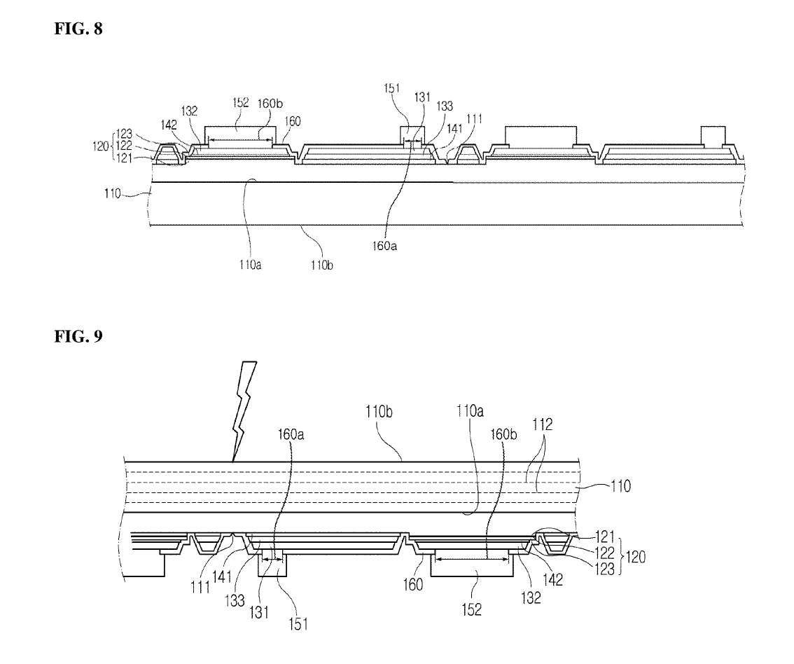

FIG. 8 to FIG. 10 are cross-sectional views depicting a method of manufacturing the light emitting device according to the second embodiment. The method of manufacturing the light emitting device according to the second embodiment is substantially similar to the method of manufacturing the light emitting device according to the first embodiment except for a process of manufacturing the substrate 110. Thus, the following description will focus on different features and description of the same components will be briefly given.

Referring to FIG. 8, a substrate 110 is prepared and semiconductor layers including a first type semiconductor layer 121, an active layer 122 and a second type semiconductor layer 123 are sequentially formed on one surface of the substrate 110. The substrate 110 may be a sapphire substrate having a thickness of 200 μm to 400 μm.

In addition, a first pad electrode 131 and a second pad electrode 132 may be formed on the first type semiconductor layer 121 and the second type semiconductor layer 123 so as to minimize contact resistance therebetween, respectively. For this purpose, a portion of the first type semiconductor layer 121 may be exposed by partially etching the active layer 122 and the second type semiconductor layer 123 and then the first pad electrode 131 may be formed on an exposed region of the first type semiconductor layer 121.

Alternatively, a first contact electrode 141 and a second contact electrode 142 may be formed to contact the first type semiconductor layer 121 and the second type semiconductor layer 123, followed by forming the first pad electrode 131 and the second pad electrode 132 on the first contact electrode 141 and the second contact electrode 142, respectively.

Furthermore, a first bump electrode 151 and a second bump electrode 152 may be formed on the first pad electrode 131 and the second pad electrode 132 for flip-chip bonding to a submount 200.

A light emitting structure 120 may be formed on a first surface 110a of the sapphire substrate 110, with a buffer layer (not shown) interposed therebetween. After formation of the light emitting structure 120, the second surface 110b may be partially removed by grinding such that the substrate 110 has a preset thickness. In consideration of durability and size of the light emitting device 100, it is desirable that the substrate 110 be subjected to grinding to a thickness of 200 μm to 400 μm.

Referring to FIG. 8, scribing lines 111 are formed on the first surface 110a of the substrate 110 to divide a plurality of light emitting structures 120 formed on the first surface 110a from one another.

The scribing lines 111 may be formed by continuous irradiation with laser beams along intended cutting lines. Here, the semiconductor layers formed on the first surface 110a of the substrate 110 are softened by irradiation with laser beams, whereby the scribing lines 111 can be formed in the form of substantially V-shaped grooves.

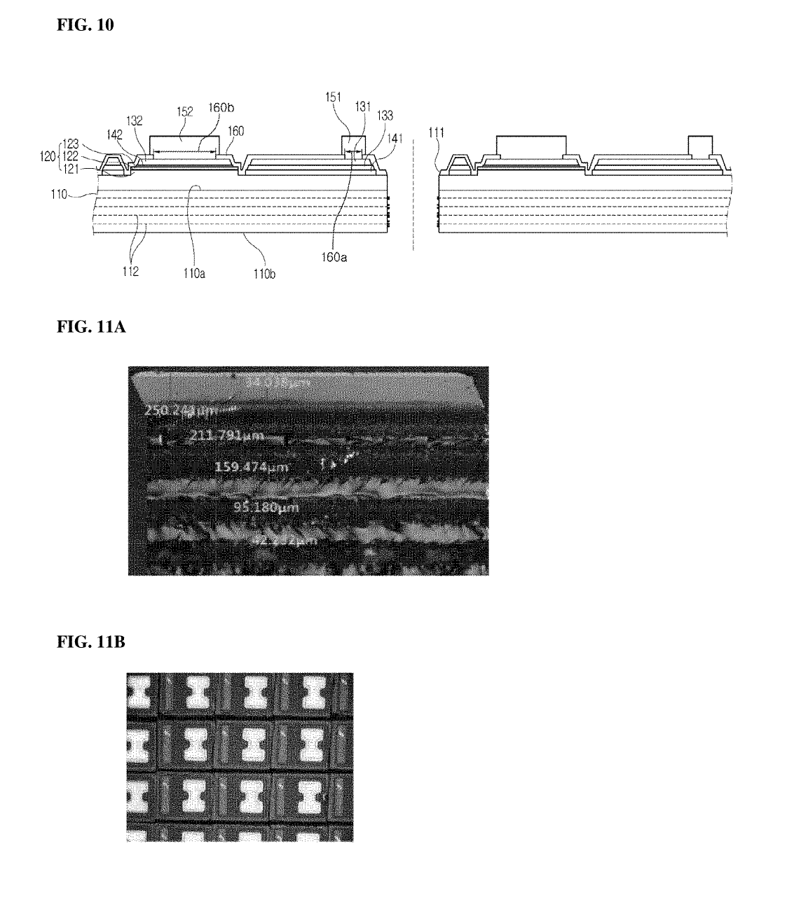

Referring to FIG. 9, inner processing lines 112 are formed within the substrate 110 by irradiation with laser beams having different wavelengths through a second surface 110b of the substrate 110.

Although the inner processing lines 112 are illustrated as being formed after formation of the scribing lines 111 in this embodiment, the inner processing lines may be formed before the scribing lines, as needed.

The plurality of inner processing lines 112 may be formed in the substrate so as to be arranged at regular intervals. The inner processing lines 112 may be parallel to each other or may not be parallel to each other.

In some implementations, the inner processing lines 112 are formed within the substrate through the second surface 110b of the substrate 110 using stealth laser beams having different wavelengths so as not to damage an outer surface of the substrate 110, particularly, the light emitting structure 120 on the first surface 110a of the substrate 110. The laser beams having different wavelengths may be output from, for example, a pulsed laser system (not shown).

In one embodiment, with the substrate 110 placed on a processing plane of a laser system, at least one pulsed laser signal is output from the laser system to form the inner processing lines 112 through generation of fine cracks inside the substrate 110. The laser signal set to form the inner processing lines 112 within the substrate 110 may be adjusted by power profile. Thereafter, the laser signal may be directed toward the substrate to form the plurality of inner processing lines 112 within the substrate 110.

In order to form the inner processing lines 112 within the substrate 110 to be separated from each other, it is necessary for the laser beam to traverse the surface of the substrate 110. To this end, at least one of the laser system and the substrate according to this embodiment is selectively movable or rotatable.

According to this embodiment, the laser system or the substrate 110 placed on the processing plane of the laser system may be moved or rotated with respect to at least one of the X-axis, the Y-axis and the Z-axis.

When the interior of the substrate 110 is irradiated with pulsed laser beams while moving or rotating the laser system or the substrate 110, the plurality of inner processing lines 112 is formed between the first surface 110a and the second surface 110b of the substrate 110, thereby causing fine cracks inside the substrate 110.

FIG. 10 shows the light emitting devices divided by the scribing lines 111. Referring to FIG. 10, with the plurality of inner processing lines 112 formed between the first surface 110a and the second surface 110b of the substrate 110, the light emitting devices divided from one another by the scribing lines 111 can be stably separated into individual chips by application of a preset pressure along the scribing lines 111. Separation of the light emitting devices into the individual chips may be realized by, for example, breaking, blade cutting, or others.

This embodiment is very useful in separation of light emitting devices formed on a very rigid substrate, such as a sapphire substrate. Thus, it is possible to achieve rapid cutting of a rigid substrate along the scribing lines 111, which are precisely formed within the substrate, through a minimized mechanical operation. As a result, it is possible to improve production yield and reliability of light emitting devices.

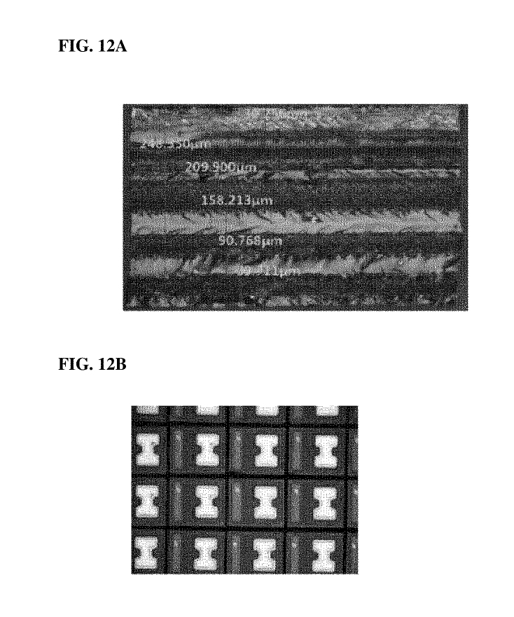

For example, in the structure wherein only a plurality of inner processing lines (four inner processing lines in one embodiment) is formed without forming a V-shaped groove in the light emitting device as shown in FIG. 11A, upon sawing for individual separation of light emitting devices as shown in FIG. 11B, it is difficult to achieve precise cutting along intended cutting line, thereby causing sawing failure and deterioration in yield of light emitting devices.

However, in the structure wherein not only the inner processing lines (four inner processing lines in one embodiment) but also the V-shaped grooves are formed in the light emitting device by laser beams as shown in FIG. 12A, upon sawing for individual separation of light emitting devices as shown in FIG. 12B, it is possible to achieve precise cutting along the intended cutting line, thereby achieving significant reduction in sawing failure and improving light emitting device yield.

A plurality of modified regions 113 each having an uneven cut surface is formed on the side surface of each of the separated light emitting devices, for example, on the side surface of the substrate 110, due to generation of fine cracks at portions thereof in which the inner processing lines 112 are formed. The modified regions 113 may have, for example, a roughness structure. The modified regions 113 increase the surface area of the side surface of each of the light emitting devices to increase the quantity of light emitted through the side surface of each of the light emitting devices, thereby improving light extraction efficiency. The modified regions 113 may have a uniform or non-uniform length and may be arranged at regular or irregular intervals.

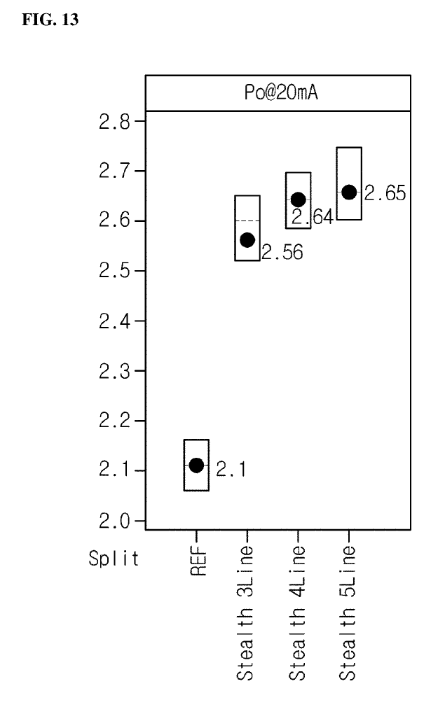

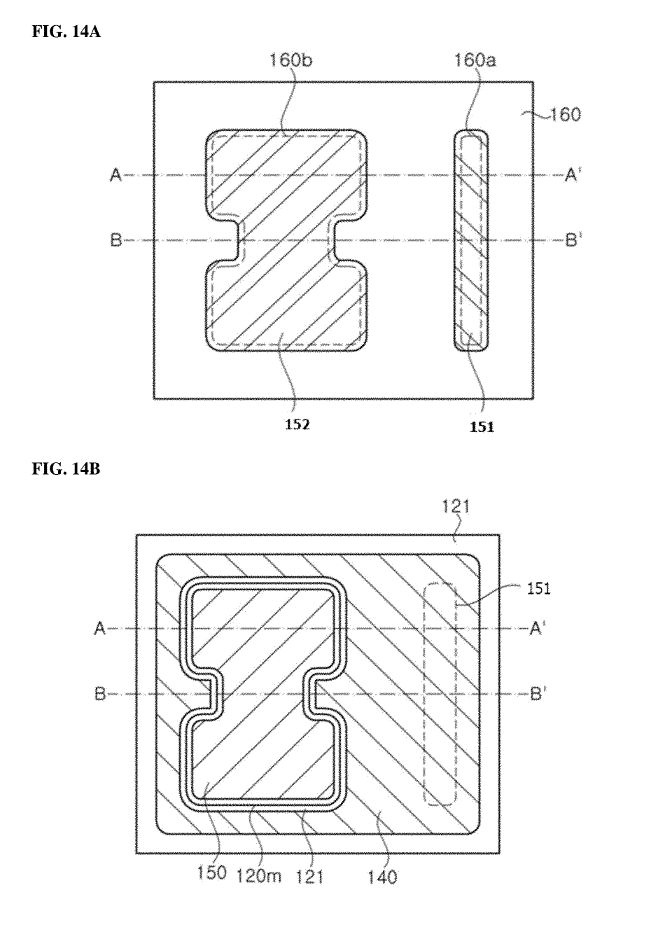

FIG. 13 is a graph depicting the relationship between luminous power Po and the number of inner processing lines in the light emitting device according to the second embodiment of the disclosed technology.

Referring to FIG. 13, after preparation of the light emitting device according to this embodiment, the luminous power Po of the light emitting device was measured upon application of an electric current of 20 mA to the light emitting device. The substrate of the light emitting device has a thickness of 250 μm.

Upon application of an electric current of 20 mA to each of the light emitting devices, a light emitting device including no inner processing line had a luminous power of 2.10 mW, a light emitting device including three inner processing lines had a luminous power of 2.56 mW, a light emitting device including four inner processing lines had a luminous power of 2.64 mW, and a light emitting device including five inner processing lines had a luminous power of 2.65 mW. This result indicates that the luminous power increases with increasing number of inner processing lines.

As compared with the increase rate of luminous power for the substrate with no inner processing line, the increase rate of luminous power of light emitted from the side surface of the substrate was increased as the number of inner processing lines was increased to 3 or more. Here, it could be seen that the increase rate of luminous power was significantly increased when the number of inner processing lines reached four, and the increase rate of the luminous power was relatively reduced when the number of inner processing lines exceeded four.

### Third Embodiment

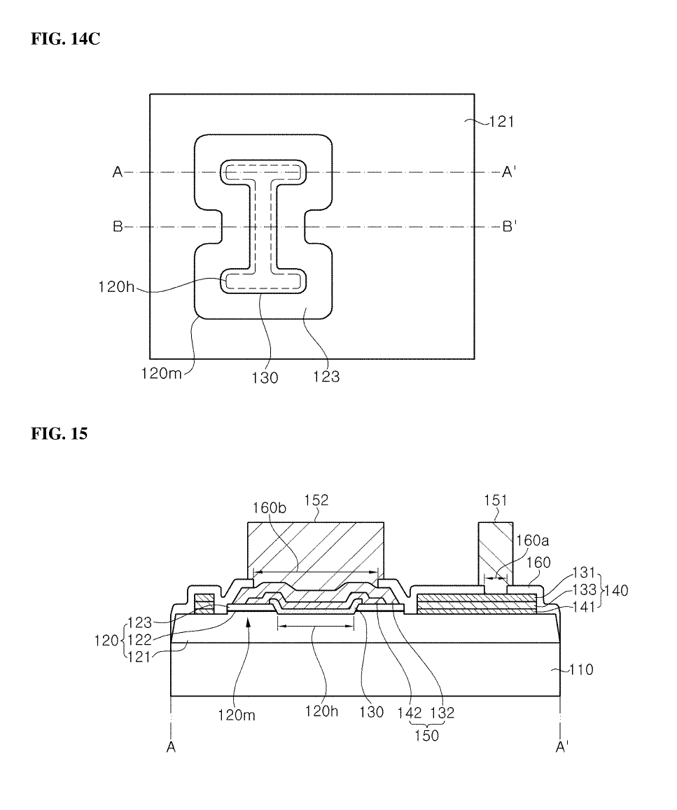

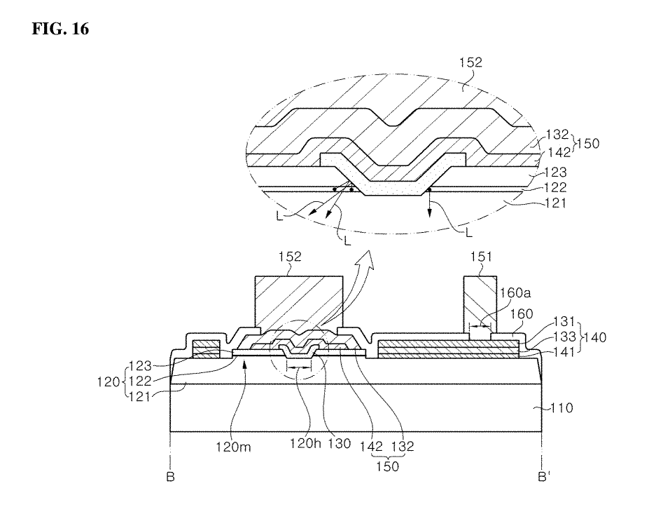

FIG. 14A to FIG. 14C are schematic plan views of a light emitting device according to a third embodiment of the disclosed technology. Specifically, FIG. 14A is a plan view of the light emitting device according to the third embodiment, FIG. 14B is a plan view of the light emitting device according to the third embodiment, in which first and second bump electrodes 151, 152 and a passivation layer 160 are omitted from the light emitting device shown in FIG. 14A for convenience of description, and FIG. 14C is a plan view of the light emitting device according to the third embodiment, in which the first and second bump electrodes 151, 152, the passivation layer 160, first and second pad electrodes 131, 132, and first and second contact electrodes 141, 142 are omitted from the light emitting device shown in FIG. 14A for convenience of description. FIG. 15 and FIG. 16 are cross-sectional views taken along lines A-A′ and B-B′ of FIG. 14A.

Referring to FIG. 14A to FIG. 16, the light emitting device according to the third embodiment includes a light emitting structure 120 including a mesa 120m, a light reflective passivation layer 130, a first pad electrode 131, and a second pad electrode 132. The UV light emitting device may further include a substrate 110, a passivation layer 160, a first contact electrode 141, a second contact electrode 142, a first bump electrode 151, and a second bump electrode 152.

The substrate 110 may be or include an insulating or conductive substrate. The substrate 110 may be a growth substrate for growth of the light emitting structure 120 thereon and may include a sapphire substrate, a silicon carbide substrate, a silicon substrate, a gallium nitride substrate, an aluminum nitride substrate, or the like. In addition, the substrate 110 includes a plurality of protrusions formed in at least some region on an upper surface thereof. The protrusions of the substrate 110 may be formed in a regular and/or irregular pattern. For example, the substrate 110 may include a patterned sapphire substrate (PSS) including a plurality of protrusions formed on the upper surface thereof. In this embodiment, a direction facing a lower surface of the substrate 110 may correspond to a main light emitting direction of the UV light emitting device.

The light emitting structure 120 is disposed on the substrate 110. The light emitting structure 120 includes a first type semiconductor layer 121, a second type semiconductor layer 123 disposed on the first type semiconductor layer 121, and an active layer 122 interposed between the first type semiconductor layer 121 and the second type semiconductor layer 123. In addition, the light emitting structure 120 may include at least one mesa 120 disposed on the first type semiconductor layer 121. The mesa 120m may include the active layer 122 and the second type semiconductor layer 123 disposed on the active layer 122.

The first type semiconductor layer 121, the active layer 122 and the second type semiconductor layer 123 may include III-V based nitride semiconductors, for example, nitride semiconductors such as (Al, Ga, In)N. The first type semiconductor layer 121 may include n-type dopants (for example, Si, Ge, Sn) and the second type semiconductor layer 123 may include p-type dopants (for example, Mg, Sr, Ba), or vice versa. The active layer 122 may include a multi-quantum well (MQW) structure and the composition ratio of the nitride-based semiconductors for the active layer 122 may be adjusted to emit light having a desired wavelength. In this embodiment, the second type semiconductor layer 123 may be a p-type semiconductor layer and the active layer 122 may be configured to emit light in the UV wavelength band. Light emitted from the active layer 122 may have a peak wavelength of 400 nm or less, specifically 365 nm or less, more specifically 300 nm or less. For example, the UV light emitting device according to this embodiment emits light having a peak wavelength of about 275 nm.

In particular, the first type semiconductor layer 121 may include a nitride semiconductor containing Al. The Al content of the first type semiconductor layer 121 may be controlled depending upon the peak wavelength of light emitted from the active layer 122. If the energy of the light emitted from the active layer 122 is greater than the energy bandgap of the first type semiconductor layer 121, the light can be absorbed by the first type semiconductor layer 121, thereby causing deterioration in luminous efficacy. Thus, the Al content of the first type semiconductor layer 121 may be controlled to provide a sufficient energy bandgap allowing the light to pass through the first type semiconductor layer 121. For example, if the active layer 122 emits light having a peak wavelength of about 275 nm, the first conductivity type semiconductor layer 121 may include a nitride semiconductor having an Al content of about 30or more. However, it should be understood that the disclosed technology is not limited thereto.

The second type semiconductor layer 123 may include at least one of p-AlGaN, p-AlInGaN, p-GaN or p-InGaN. Further, the second type semiconductor layer 123 may include a nitride semiconductor having an energy bandgap of 3.0 eV to 4.0 eV. In one embodiment, the second type semiconductor layer 123 may include p-GaN or may be formed of p-GaN. The second type semiconductor layer 123 including p-GaN or formed of p-GaN can easily form ohmic contact with a portion of the second contact electrode 142 and a portion of the second pad electrode 132 while reducing contact resistance, thereby improving electrical characteristics of the UV light emitting device. However, it should be understood that the disclosed technology is not limited thereto.

In the light emitting structure 120, the mesa 120m is disposed on the first type semiconductor layer 121. The mesa 120m may include portions having different widths in a plan view. The mesa 120m may include a portion having a relatively large width and a portion having a relatively small width. For example, the mesa 120m may have a shape with at least one indentation formed on a side surface thereof, in which a region around the indentation corresponds to the portion having a relatively small width. Such a mesa 120m may have an H shape, an I shape, a dumbbell shape, or the like. In addition, the mesa 120m may include at least one hole 120h formed through the second type semiconductor layer 123 and the active layer 122 to expose the first type semiconductor layer 121. Here, in the mesa 120m, the portion having a relatively small width may include at least a portion of the hole 120h. Further, the portion of the hole 120h included in the portion having a relatively small width may have an elongated shape extending in a perpendicular direction with respect to the width.

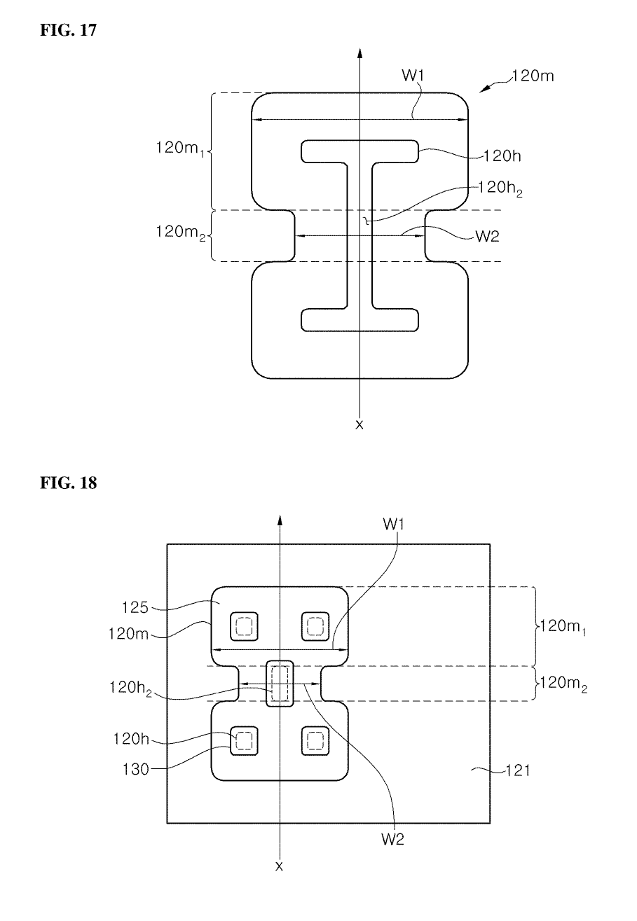

Next, the mesa 120m and the hole 120h will be described in more detail with reference to FIG. 17. FIG. 17 is a plan view illustrating the mesa and the hole of the light emitting device according to the third embodiment of the disclosed technology.

Referring to FIG. 17, the mesa 120m may include an upper surface including a first portion 120m₁ having a first width W1 and a second portion 120m₂ having a second width W2. The first width W1 and the second width W2 are defined as widths perpendicular with respect to Line X, which is an arbitrary vector line passing through the mesa 120m. Each of the first portion 120m₁ and the second portion 120m₂ may include a portion having a varying width. For example, the second portion 120m₂ may be connected to the first portion 120m₁ to have a varying width. Here, in the second portion 120m₂, the width of the portion having a varying width may be smaller than the first width W 1. The mesa 120m may include at least one first portion 120m₁ and at least one second portion 120m₂. In this embodiment, the mesa 120m may include two first portions 120m₁ and the second portion 120m₂ may be interposed between the two first portions 120m₁. Accordingly, the mesa 120m may have an H shape or an I shape in a plan view. Alternatively, the mesa 120m may have a shape in which circles or ovals overlap, or a dumbbell shape. The mesa 120m may include two or more second portions 120m₂.

The at least one hole 120h is formed to partially penetrate the first portion 120m₁ and the second portion 120m₂ of the mesa 120m a. The portion of the hole 120h which is formed on the second portion 120m₂ is indicated by 120h₂. In some implementations, the portion of the hole 120h included in the second portion 120m₂ may have an elongated shape extending in the perpendicular direction with respect to the second width W1 of the hole 120h. For example, as shown in FIG. 17, the hole 120h may have a similar shape to that of the mesa 120m in a plan view in that the portions of the hole 120h in the first portions 120m₁ of the mesa 120m have a width greater than the portion of the hole 120h₂ in the second portion 120m₂ of the mesa 120m. In some implementations, the hole 120h may have an I shape or an H shape. Some portions of the hole 120h may be included in the first portions 120m₁ and the other portions of the hole 120h may be included in the second portions 120m₂. The portion of the hole 120h included in the second portion 120m₂ may have an elongated shape extending along the vector line x, which is perpendicular to the second width W2. That is, when the direction of the vector line x is defined as the transverse direction, the portion of the hole 120h₂ included in the second portion 120m₂ may have a shape, a transverse width of which is greater than a longitudinal width thereof.

In various embodiments, the mesa 120m may include a plurality of holes 120h. Referring to FIG. 18, the mesa 120m may include the plurality of holes 120h, which are arranged at substantially constant intervals. In this structure, at least one of the holes 120h may be included in the second portion 120m₂. The portion of the hole 120h₂ included in the second portion 120m₂ may have an elongated shape extending in the direction of the vector line X. In other embodiments, the second portion 120m₂ may include a plurality of holes 120h₂. In these embodiments, at least one of the holes 120h₂ included in the second portion 120m₂ may have an elongated shape extending in the direction of the vector line x.

Referring again to FIG. 14A to FIG. 17, the light reflective passivation layer 130 is disposed on the mesa 120m and partially covers a surface of at least one hole 120h. That is, the light reflective insulation layer 130 may cover an upper surface of the first type semiconductor layer 121 exposed through the hole 120h and a side surface of the hole 120h. In addition, the light reflective insulation layer 130 may further cover an upper surface of the mesa 120m around the hole 120h. Here, the second electrode 150 may be electrically connected to the second type semiconductor layer 123 through an exposed portion thereof not covered by the light reflective insulation layer 130. The structure of the light reflective insulation layer 130 covering the hole 120h prevents electric short through electrical connection of the second pad electrode 132 and the second contact electrode 142 to the active layer 122 or the first type semiconductor layer 121.

The light reflective insulation layer 130 may have electrically insulating properties and optical reflectivity. In particular, the light reflective insulation layer 130 according to this embodiment may have reflectivity with respect to UV light. The light reflective insulation layer 130 may include a distributed Bragg reflector. The distributed Bragg reflector may be formed by alternately stacking dielectric layers having different indices of refraction. For example, the dielectric layers may include at least one of TiO₂, SiO₂, HfO₂, ZrO₂, Nb₂O₅, or MgF₂, and or others. In some embodiments, the light reflective insulation layer 130 may include a distributed Bragg reflector of SiO₂/ZrO₂ layers alternately stacked one above another. In the distributed Bragg reflector, each layer may have an optical thickness of λ/4 and the distributed Bragg reflector may be composed of 4 to 40 pairs of these layers. In addition, the distributed Bragg reflector may include a first distributed Bragg reflector reflecting light having a relatively long wavelength and a second distributed Bragg reflector reflecting light having a relatively short wavelength. In addition, the lowermost layer of the distributed Bragg reflector may include an interfacial layer having a relatively thick thickness.

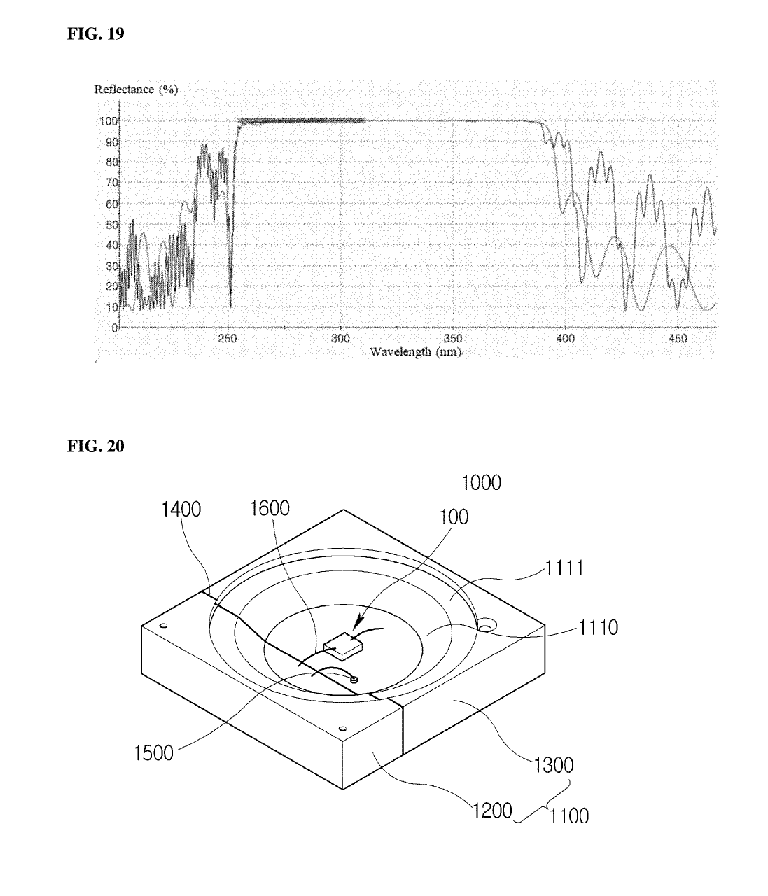

For example, the light reflective insulation layer 130 may include an interfacial layer formed of or including SiO₂, a first distributed Bragg reflector disposed on the interfacial layer, and a second distributed Bragg reflector disposed on the first distributed Bragg reflector. Each of the first distributed Bragg reflector and the second distributed Bragg reflector may include a stacked structure in which ZrO₂ layers and SiO₂ layers are alternately stacked one above another. In this embodiment, the first distributed Bragg reflector can reflect light having a relatively long wavelength and the second distributed Bragg reflector can reflect light having a relatively short wavelength. Accordingly, the ZrO₂ layer and the SiO₂ layer of the first distributed Bragg reflector may have a greater average thickness than the ZrO₂ layer and the SiO₂ layer of the second distributed Bragg reflector. Further, each of the first and second distributed Bragg reflectors may have a stacked structure of 10 pairs of ZrO₂/SiO₂ layers. Accordingly, the light reflective insulation layer 130 has a structure in which an SiO₂ layer (interfacial layer) is placed at the lowermost side and another SiO₂ layer (the uppermost layer of the second distributed Bragg reflector) is placed at the uppermost side, and in which a total of 41 layers composed of ZrO₂ and SiO₂ layers are alternatively stacked one above another. Accordingly, as shown in FIG. 19, the light reflective insulation layer 130 according to this embodiment has a reflectance of 90% or more, specifically 95% or more, with respect to light having a wavelength of 250 nm to 375 nm. Particularly, the second distributed Bragg reflector reflecting light having a relatively short wavelength is disposed on the first distributed Bragg reflector reflecting light having a relatively long wavelength, thereby realizing a distributed Bragg reflector having a very high reflectance with respect to light in the wavelength range of about 250 nm to 375 nm.

Light emitted from the active layer 122 is reflected by the light reflective insulation layer 130. As shown in an enlarged circle of FIG. 16, light L emitted from the active layer 122 is reflected by the light reflective insulation layer 130 to travel toward the bottom of the substrate before completely passing through the second type semiconductor layer 123. As a result, the light reflective insulation layer 130 can prevent deterioration in luminous efficacy through absorption of the light L by the second type semiconductor layer 123. Hereinafter, this structure will be described in more detail.

A first electrode 140 is disposed on the first type semiconductor layer 121 and is electrically connected to the first type semiconductor layer 121. Furthermore, the first electrode 140 may form ohmic contact with the first type semiconductor layer 121. The first electrode 140 may cover at least part of the upper surface of the first type semiconductor layer 121 excluding a region in which the mesa 120m is disposed. In one embodiment, the first electrode 140 may be formed to cover the upper surface of the first type semiconductor layer 121 while surrounding the mesa 120m, as shown in FIG. 2. The first electrode 140 may be formed to cover about 50% of the upper surface of the first type semiconductor layer 121. With this structure, the first electrode 140 can improve current spreading efficiency to improve electrical characteristics of the UV light emitting device and can reflect light having entered the first type semiconductor layer 121 toward the bottom of the substrate 110, thereby improving luminous efficacy.

The first electrode 140 may include a metallic material, for example, Ni, Pt, Pd, Rh, W, Ti, Al, Mg, Ag, Au, Cr, or others, or a combination thereof. The first electrode 140 may be composed of a single layer or multiple layers. In one embodiment, the first electrode 140 may include a first contact electrode 141, a pad layer 133, and a first pad electrode 131. The first contact electrode 141 may form ohmic contact with the first type semiconductor layer 121 and may include at least one of Cr, Ti, Al or Au. For example, the first contact electrode 141 may have a multilayer structure of Cr/Ti/Al/Ti/Au. The pad layer 133 may include Ti or Au and may have a multilayer structure of, for example, Ti/Au. The first pad electrode 131 may be formed of a material exhibiting good adhesion to the first bump electrode 151. For example, the first pad electrode 131 may include Ti or Au and may have a multilayer structure of, for example, Ti/Au. Further, the first electrode 140 may have an inclined side surface.

A second electrode 150 is disposed on the mesa 120m and covers the light reflective insulation layer 130. The second electrode 150 contacts an upper surface of the second type semiconductor layer 123 to be electrically connected thereto, and is separated from the side surface of the hole 120h and the first type semiconductor layer 121 by the light reflective insulation layer 130 so as to be insulated therefrom. The second electrode 150 includes a second contact electrode 142 and a second pad electrode 132 at least partially covering the second contact electrode 142. The second contact electrode 142 reflects UV light and may be formed of a material forming ohmic contact with the second type semiconductor layer 123. For example, the second contact electrode 142 may include at least one of Ni, Pt, Pd, Rh, W, Ti, Al, Mg, Ag, or Au. Particularly, the second contact electrode 142 may include Al. In addition, the second contact electrode 142 may be composed of a single layer or multiple layers. The second pad electrode 132 can prevent interdiffusion between the second contact electrode 142 and other materials and damage to the second contact electrode 142 through diffusion of external materials into the second contact electrode 142. The second pad electrode 132 may include, for example, Au, Ni, Ti, Cr, Pt, W, and the like, and may be composed of a single layer or multiple layers. With such a structure, the second electrode 150 can reflect light emitted from the active layer 122 toward the bottom of the substrate 110.

The passivation layer 160 may cover the light emitting structure 120, the first electrode 140 and the second electrode 150, and may include a first opening 160a and a second opening 160b that partially expose the first electrode 140 and the second electrode 150, respectively. The passivation layer 160 may cover the light emitting structure 120, the first electrode 140 and the second electrode 150 excluding the first and second openings 160a, 160b to protect the UV light emitting device. Each of the first and second electrodes 140, 150 may be electrically connected to other portions through the first and second openings 160a, 160b of the passivation layer 160.

The first bump electrode 151 and the second bump electrode 152 may be disposed on the passivation layer 160 to be electrically connected to the first electrode 140 and the second electrode 150 through the first and second openings 160a, 160b, respectively. In addition, each of the first bump electrode 151 and the second bump electrode 152 may cover an upper surface of the passivation layer 160 around the first and second openings 160a, 160b. In this case, an upper surface of each of the first and second bump electrodes 151, 152 may protrude by the thickness of the passivation layer 160. Alternatively, the first and second bump electrodes 151, 152 may be disposed within the first and second openings 160a, 160b and may be at least partially separated from the passivation layer 160.

The first bump electrode 151 may be disposed on the first opening 160a in a region separated from the mesa 120m. The second bump electrode 152 may be disposed on the second opening 160b and the mesa 120m. The second bump electrode 152 may have a substantially similar shape to the mesa 120m and the second opening 160b may also have a substantially similar shape to the mesa 120m in a plan view. Thus, the second bump electrode 152 may have an H shape, an I shape, or a dumbbell shape in a plan view. Since the second bump electrode 152 has a substantially similar shape to the mesa 120m and the second electrode 150 in a plan view, the UV light emitting device can have improved current spreading efficiency, thereby improving electrical characteristics thereof.

Each of the first bump electrode 151 and the second bump electrode 152 may be composed of a single layer or multiple layers. With the multilayer structure, each of the first bump electrode 151 and the second bump electrode 152 may include, for example, an adhesive layer, an anti-diffusion layer and a bonding layer. The adhesive layer may include, for example, Ti, Cr or Ni, the anti-diffusion layer may include Cr, Ni, Ti, W, TiW, Mo, or Pt or a combination thereof, and the bonding layer may include Au or AuSn.

According to the embodiment described above, the UV light emitting device has the mesa 120m include at least one hole 120h. The surface of the hole 120h is covered by the light reflective insulation layer 130 including the distributed Bragg reflector, in which the light reflective insulation layer 130 reflects light L emitted from the active layer 122, thereby improving luminous efficacy of the UV light emitting device.

In the UV light emitting device, UV light emitted from the active layer 122 has high energy. The UV light with such high energy is at least partially absorbed by a nitride semiconductor having a lower energy bandgap than the energy of the UV light. Accordingly, in order to prevent absorption of light by a p-type semiconductor layer of the UV light emitting device, that is, the second type semiconductor layer 123, the p-type semiconductor is required to have a higher energy bandgap than the energy of light emitted from the active layer 122. For example, in order to minimize absorption of light having a peak wavelength of 300 nm or less by the second type semiconductor layer 123, it is desirable that the second type semiconductor layer be formed of or include a nitride semiconductor 123 having an Al content of 40% or more. However, a nitride semiconductor layer having a high Al content exhibits poor contact characteristics with the second electrode 150 to deteriorate electrical characteristics of the UV light emitting device, thereby deteriorating luminous efficacy. Accordingly, even considering the absorption ratio of UV light by the second type semiconductor layer 123, the second type semiconductor layer 123 may be formed of or include p-GaN having an energy bandgap of about 3.4 eV to improve electrical characteristics of the UV light emitting device in order to realize a UV light emitting device having further improved luminous efficacy.

According to the embodiments, as shown in an enlarged view of FIG. 16, the hole 120h is formed in the mesa 120m such that light L emitted from the active layer 122 is reflected by the light reflective insulation layer 130 instead of completely passing through the second type semiconductor layer 123. As a result, loss of light L through absorption by the second type semiconductor layer 123 is suppressed by reducing the length of a path along which the light L passes through the second type semiconductor layer 123. Accordingly, it is possible to improve luminous efficacy of the UV light emitting device. Particularly, since the second type semiconductor layer 123 having an energy bandgap of 3.0 eV to 4.0 eV has a high absorption rate with respect to UV light having a relatively low peak wavelength, the UV light emitting device according to this embodiment can have further improved luminous efficacy upon emission of light having a peak wavelength of about 300 nm or less.

Furthermore, the UV light emitting device includes the mesa 120m, which includes the portion having a relatively small width, that is, the second portion 120m₂. Here, the second portion 120m₂ may include a hole 120h₂ (extending in the direction of the vector line X), which has an elongated shape extending in the perpendicular direction with respect to the width of the second portion 120m₂. Since the second portion 120m₂ is disposed between the first portions 120m₁, current crowding can occur in the second portion 120m₂ and intense light emission is likely to occur in the second portion 120m₂. Accordingly, with the structure wherein the hole 120h₂ is formed to extend in the perpendicular direction with respect to the width of the second portion 120m₂ and the light reflective insulation layer 130 is formed to cover the hole 120h₂, the UV light emitting device can reduce the ratio of light absorbed by the second type semiconductor layer 123 in the second portion 120m₂ while allowing light to be more easily emitted from a side surface of the second portion 120m₂. With this structure, the UV light emitting device can have further improved luminous efficacy.

### EXPERIMENTAL EXAMPLE

A UV light emitting device (Example 1) as shown in FIG. 14A to FIG. 17, a UV light emitting device (Example 2) as shown in FIG. 18, and a UV light emitting device (Comparative Example) including a mesa free from a hole were prepared to compare luminous power and electrical characteristics. The UV light emitting device of Comparative Example had a substantially similar structure to the UV light emitting device shown in FIG. 14A to FIG. 17 except that the UV light emitting device of Comparative Example does not include a hole. The characteristics and experimental results of the UV light emitting devices of Examples 1 and 2 and Comparative Example 1 are shown in Table 2.

TABLE 2

| | | Luminous | | | | | |
|---|---|---|---|---|---|---|---|
| | Surface | area | | | | | |
| | area of light | (surface | | Forward | | Luminous | |
| | reflective | area of | | voltage | | power | |
| | insulation | active | Current | (Vf) | | (Po) | |
| | layer | layer) | density | (@20 mA) | | (@20 mA) | |
| | (μm²) | (μm²) | (A/cm²) | Vf | Ratio | Po | Ratio |
| Comparative | | 38,380 | 52.11 | 6.486 | | 2.1439 | |
| Example | | | | | | | |
| Example 1 | 3,490 | 38,494 | 51.96 | 6.432 | −0.833% | 2.2593 | 5.383% |
| Example 2 | 3,168 | 38,360 | 52.14 | 6.454 | −0.493% | 2.2349 | 4.245% |

As shown in Table 2, it can be seen that, despite substantially the same luminous area, the light emitting devices of Examples 1 and 2 had lower forward voltages and higher luminous power than the light emitting device of Comparative Example. As such, according to the embodiments, the UV light emitting device has improved electrical characteristics and luminous efficacy.

FIG. 20 is a perspective view of a light emitting device package using a light emitting device according to embodiments of the disclosed technology. Here, the light emitting device may include all of the light emitting devices according to the first to third embodiments.

Referring to FIG. 20, a light emitting device package 1000 according to this embodiment includes a package body 1100 and a light emitting device 100 mounted on the package body 1100.

The package body 1100 has a cavity 1110 formed on one surface thereof and an inclined surface 1111 formed around the light emitting device 100. The inclined surface 1111 can improve light extraction efficiency of the light emitting device package.

The package body 1100 is divided into a first electrode portion 1200 and a second electrode portion 1200 by an insulating portion 1400 such that the first electrode portion 1200 is electrically insulated from the second electrode portion 1200.

The package body 1100 may include a silicone material, a synthetic resin material, or a metallic material. For example, in order to improve heat dissipation upon emission of UV light from the light emitting device 100, the package body 1100 may be formed of aluminum. Accordingly, the first electrode portion 1200 and the second electrode portion 1300 can improve luminous efficacy by reflecting light emitted from the light emitting device 100 and can serve to dissipate heat from the light emitting device 100.

The light emitting device 100 may be electrically connected to the first electrode portion 1200 and the second electrode portion 1300 via a connection member 1600, such as a metal wire, such that electric power can be supplied to the light emitting device 100 therethrough.

In a state of being mounted on a submount 200, the light emitting device 100 may be placed on the cavity 1100 of the package body 1100 and electrically connected to the first electrode portion 1200 and the second electrode portion 1300. Reference numeral 1500 indicates a Zener diode, which is a voltage regulator diode.

Technical features of each of the light emitting devices according to the first to third embodiments may also be applied to other embodiments without departing from the scope of the disclosed technology. For example, the features of the scribing line 111 and the inner processing lines 112 of the substrate 110 according to the second embodiment may also be applied to the substrates 110 according to the first and third embodiments.

Although some embodiments have been described herein, it should be understood that these embodiments are provided for illustration only and are not to be construed in any way as limiting the disclosed technology. It should be understood that various modifications, changes, alterations, and equivalent embodiments can be made by those skilled in the art without departing from the spirit and scope of the disclosed technology.

I/We claim:

1. A UV light emitting device comprising:
a substrate having a first surface and a second surface facing the first surface; and
a light emitting structure formed on the first surface of the substrate and comprising a first type semiconductor layer, an active layer emitting UV light, and a second type semiconductor layer,
wherein a ratio of surface area of the substrate to luminous area of the light emitting structure is equal to or less than 6.5.

2. The UV light emitting device according to claim 1, wherein the substrate has a thickness of 200 μm to 400 μm.

3. The UV light emitting device according to claim 1, wherein the substrate has a surface area of 350 μm×410 μm to 550 μm×550 μm.

4. The UV light emitting device according to claim 1, wherein the substrate comprises at least one of sapphire (Al₂O₃), SiC, Si, GaAs, GaN, ZnO, Si, GaP, InP, Ge, or AlN.

5. The UV light emitting device according to claim 1, wherein the substrate comprises a plurality of modified regions formed on the second surface or a side surface of the substrate.

6. The UV light emitting device according to claim 1, wherein the light emitting structure has a luminous area of 35,000 μm² to 40,000 μm².

7. The UV light emitting device according to claim 1, wherein the luminous area of the light emitting structure is a surface area of the active layer.

8. The UV light emitting device according to claim 1, further comprising:
a first contact electrode formed on the first type semiconductor layer and comprising a reflective material.

9. The UV light emitting device according to claim 1, further comprising:
a submount to which the light emitting device is flip-chip bonded.

10. A UV light emitting device comprising:
a substrate having a first surface and a second surface facing the first surface, the substrate formed with at least one inner processing line between the first surface and the second surface;
light emitting structures formed on the first surface of the substrate and emitting UV light; and
a scribing line formed on the first surface of the substrate and disposed between adjacent light emitting structures.

11. The UV light emitting device according to claim 10, wherein the number of inner processing lines is three or more.

12. The UV light emitting device according to claim 11, wherein the inner processing lines are separated parallel to each other.

13. The UV light emitting device according to claim 10, wherein the inner processing line is formed by irradiation with pulsed laser beams.

14. The UV light emitting device according to claim 10, wherein the scribing line may include a V-shaped groove.

15. The UV light emitting device according to claim 14, wherein the scribing line is formed by laser irradiation.

16. The UV light emitting device according to claim 10, wherein the substrate has a thickness of 200 μm to 400 μm.

17. The UV light emitting device according to claim 10, wherein the light emitting structure comprises a first type semiconductor layer, an active layer, and a second type semiconductor layer, and a first contact electrode comprising a reflective material is formed on the first type semiconductor layer.

18. A UV light emitting device comprising:
a first type semiconductor layer;
a mesa comprising an active layer disposed on the first conductivity type semiconductor layer and emitting UV light and a second conductivity type semiconductor layer disposed on the active layer, the mesa having at least one hole formed through the active layer and the second conductivity type semiconductor layer to partially expose the first conductivity type semiconductor layer;
a light reflective insulation layer at least partially covering a surface of the hole and comprising a distributed Bragg reflector;
a first electrode electrically connected to the first conductivity type semiconductor layer; and
a second electrode disposed on the mesa to cover the light reflective insulation layer and electrically connected to the second conductivity type semiconductor layer,
wherein the mesa comprises:
a first portion having a first width; and
a second portion having a second width smaller than the first width on an upper surface of the mesa, and the second portion includes at least a portion of the hole.

19. The UV light emitting device according to claim 18, wherein the portion of the hole included in the second portion has an elongated shape extending in a perpendicular direction with respect to the second width.

20. The UV light emitting device according to claim 18, wherein the mesa comprises at least two first portions and the second portion is disposed between the two first portions.

21. The UV light emitting device according to claim 20, wherein the mesa has an H shape in a plan view.

22. The UV light emitting device according to claim 21, wherein the hole has an H shape in the plan view.

23. The UV light emitting device according to claim 18, wherein the mesa comprises a plurality of holes, at least one of the plurality of holes included in the second portion, and the at least one hole included in the second portion has an elongated shape extending in a perpendicular direction with respect to the second width.

24. The UV light emitting device according to claim 18, wherein the light reflective insulation layer covers an upper surface of the mesa around the hole.

25. The UV light emitting device according to claim 18, wherein a surface of the first conductivity type semiconductor layer exposed through the hole is separated from the second electrode by the light reflective insulation layer to be electrically insulated therefrom.

26. The UV light emitting device according to claim 18, wherein the distributed Bragg reflector of the light reflective insulation layer comprises a stacked structure in which ZrO₂ layers and SiO₂ layers are repeatedly stacked one above another.

27. The UV light emitting device according to claim 26, wherein the light reflective insulation layer further comprises an interfacial layer disposed under the distributed Bragg reflector, the interfacial layer including SiO₂ and having a greater thickness than the ZrO₂ layer and the SiO₂ layer of the distributed Bragg reflector.

28. The UV light emitting device according to claim 18, wherein the light reflective insulation layer comprises:
a first distributed Bragg reflector reflecting light having a relatively long wavelength; and
a second distributed Bragg reflector disposed on the first distributed Bragg reflector and reflecting light having a relatively short wavelength.

29. The UV light emitting device according to claim 18, wherein the second type semiconductor layer comprises a nitride semiconductor having an energy bandgap of 3.0 eV to 4.0 eV.

30. The UV light emitting device according to claim 29, wherein the second type semiconductor layer comprises P-GaN.

31. The UV light emitting device according to claim 29, wherein the active layer emits light having a peak wavelength of 300 nm or less.

32. The UV light emitting device according to claim 18, wherein the first electrode covers 50% or more of an upper surface of the first type semiconductor layer.

33. The UV light emitting device according to claim 18, further comprising:
a passivation layer covering the first electrode and the second electrode and comprising a first opening and a second opening partially exposing the first electrode and the second electrode, respectively.

34. The UV light emitting device according to claim 33, further comprising:
a first pad electrode disposed on the passivation layer and electrically connected to the first electrode through the first opening; and
a second pad electrode disposed on the passivation layer and electrically connected to the second electrode through the second opening.

35. A UV light emitting device comprising:
a first type semiconductor layer;
a mesa comprising an active layer disposed on the first conductivity type semiconductor layer and emitting UV light, and a second conductivity type semiconductor layer disposed on the active layer, the mesa having at least one hole formed through the active layer and the second conductivity type semiconductor layer to partially expose the first conductivity type semiconductor layer;
a light reflective insulation layer at least partially covering a surface of the hole and comprising a distributed Bragg reflector; and
a second electrode disposed on the mesa to cover the light reflective insulation layer and electrically connected to the second conductivity type semiconductor layer,
wherein the mesa comprises: a first portion having a first width in a perpendicular direction with respect to a vector line having an arbitrary direction on an upper surface of the mesa; and a second portion having a second width in the perpendicular direction with respect to the vector line, the first width being greater than the second width, the second portion includes at least a portion of the hole, and
portion of the hole included the second portion has an elongated shape extending in a direction of the vector line.

36. The UV light emitting device according to claim 35, wherein the second electrode comprises a second contact electrode and a second pad electrode covering the second contact electrode.

37. The UV light emitting device according to claim 35, wherein the distributed Bragg reflector comprises a stacked structure in which ZrO₂ layers SiO₂ layers repeatedly stacked one above another.
